(19) United States
(12) Patent Application Publication
(10) Pub. No.: US 2026/0344320 A1
(43) Pub. Date: Oct. 29, 2026

(54) METHOD FOR MANUFACTURING SEMICONDUCTOR DEVICE

(71) Applicant: EPISIL TECHNOLOGIES INC., Hsinchu County (TW)

(72) Inventors: Hsueh-Cheng WU, Hsinchu County (TW); Zhi-Wei LIN, Hsinchu County (TW); Chin-Hao HSU, Hsinchu County (TW)

(21) Appl. No.: 19/258,189

(22) Filed: Jul. 2, 2025

(30) Foreign Application Priority Data
Apr. 24, 2025 (TW) 114115526

(51) Int. Cl. H10P 50/00; H10P 50/66

(52) U.S. Cl. CPC H10P 50/71; H10P 50/667; H10P 50/692; H10P 50/73

(57) ABSTRACT

A method for manufacturing a semiconductor device includes the steps of: a) sequentially forming a conductive material layer and a dielectric material layer on a semiconductor unit along a growth direction; b) forming a photoresist material layer on the dielectric material layer along the growth direction; c) patterning the photoresist material layer to form a photoresist layer; d) patterning the dielectric material layer and the conductive material layer using the photoresist layer as a mask so as to respectively form a dielectric layer and a conductive layer; and e) removing the photoresist layer, followed by patterning the semiconductor unit using the dielectric layer as a mask.

### CROSS-REFERENCE TO RELATED APPLICATION

This application claims priority to Taiwanese Invention Patent Application No. 114115526, filed on Apr. 24, 2025, the entire disclosure of which is incorporated by reference herein.

### FIELD

The disclosure relates to a method for manufacturing a semiconductor device, and more particularly to a method for manufacturing a high electron mobility transistor.

### BACKGROUND

A high electron mobility transistor (HEMT), which is a field-effect transistor, has been widely used in integrated circuits. The HEMT includes a heterogeneous interface which is formed by two materials having different energy bandgap levels, so that a conductive channel (e.g., a two-dimensional electron gas (2DEG)) is able to be formed naturally at the heterogeneous interface, and thus the HEMT exhibits high electron mobility characteristics.

A conventional method for manufacturing an HEMT is exemplified in FIGS. 1-4. Referring to FIG. 1, a barrier layer 92, a p-doped material layer 93’ and a conductive material layer 94’ are sequentially formed on a semiconductor layer 91 in a growth direction (G). Next, a patterned first photoresist layer 95 is formed on the conductive material layer 94’. Then, the conductive material layer 94’ is patterned using the patterned first photoresist layer 95 as a mask so as to form a conductive layer 94 as shown in FIG. 2. Referring to FIG. 3, a patterned second photoresist layer 96 is formed on the conductive layer 94 in the growth direction (G). Then, the p-doped material layer 93’ is patterned using the patterned second photoresist layer 96 as a mask so as to form a p-doped layer 93 as shown in FIG. 4.

However, the aforesaid method employs photoresist-involved photolithography processes twice to separately pattern the conductive material layer 94’ and the p-doped material layer 93’, which makes the method more complicated. In addition, theoretically, a position of the patterned second photoresist layer 96 shall be identical to a position of the patterned first photoresist layer 95 so that the conductive layer 94 and the p-doped layer 93 may be perfectly aligned with each other. However, misalignment between the conductive layer 94 and the p-doped layer 93 (see FIG. 4) might occur due to an alignment deviation of an aligner, leading to a reduced manufacturing yield.

### SUMMARY

Therefore, an object of the disclosure is to provide a method that can alleviate at least one of the drawbacks of the prior art.

According to the disclosure, the method for manufacturing a semiconductor device includes the steps of:

a) sequentially forming a conductive material layer and a dielectric material layer on a semiconductor unit along a growth direction;
b) forming a photoresist material layer on the dielectric material layer along the growth direction;
c) patterning the photoresist material layer to form a photoresist layer;
d) patterning the dielectric material layer and the conductive material layer using the photoresist layer as a mask so as to respectively form a dielectric layer and a conductive layer; and
e) removing the photoresist layer, followed by patterning the semiconductor unit using the dielectric layer as a mask.

### BRIEF DESCRIPTION OF THE DRAWINGS

Other features and advantages of the disclosure will become apparent in the following detailed description of the embodiment(s) with reference to the accompanying drawings. It is noted that various features may not be drawn to scale.

FIGS. 1 - 4 are schematic views illustrating a conventional method for manufacturing a high electron mobility transistor.

FIG. 5 is a flow diagram illustrating an embodiment of a method for manufacturing a semiconductor device of the present disclosure.

FIG. 6 is a schematic view illustrating step a) and step b) shown in FIG. 5.

FIG. 7 is a schematic view illustrating step c) and step d) shown in FIG. 5.

FIG. 8 is a schematic view illustrating step e) shown in FIG. 5.

FIG. 9 is a schematic view illustrating step e) shown in FIG. 5.

FIG. 10 is a schematic view illustrating step f) shown in FIG. 5.

FIG. 11 is a schematic view illustrating step f) shown in FIG. 5.

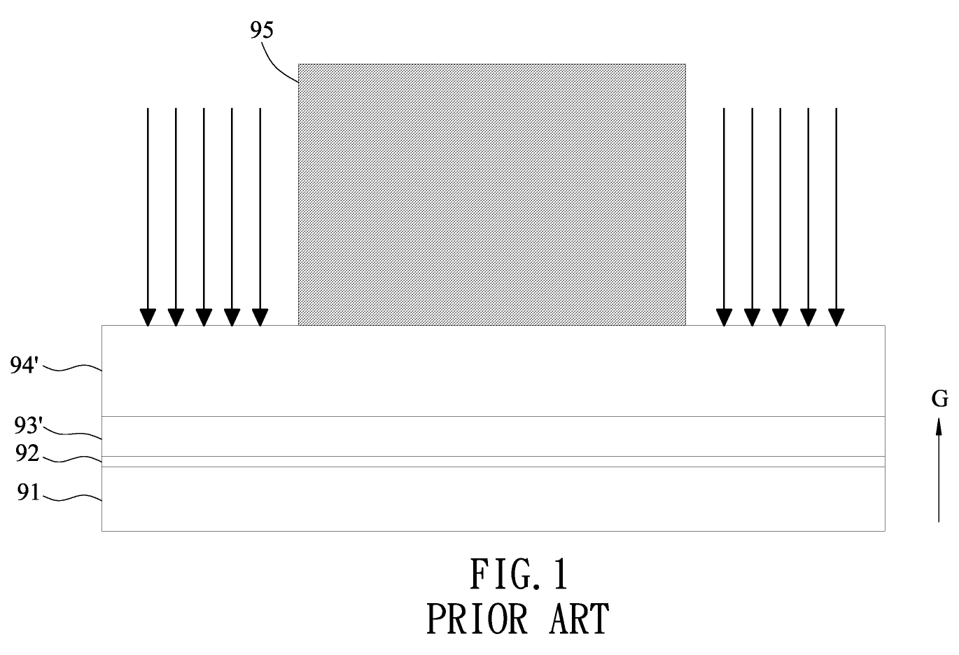

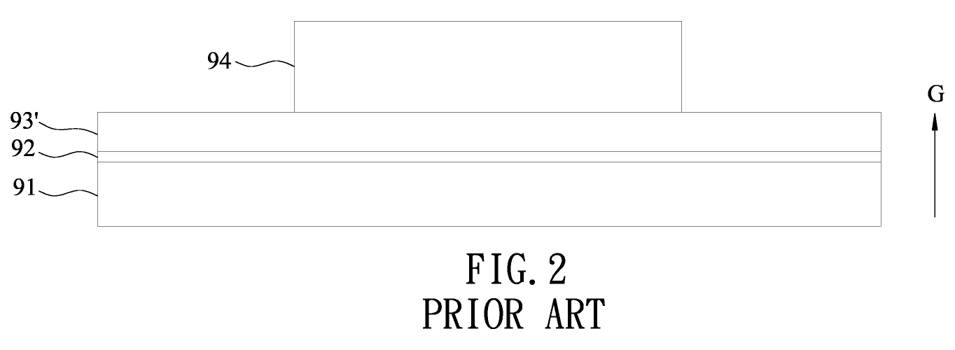

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

It should be noted herein that for clarity of description, spatially relative terms such as “top,” “bottom,” “upper,” “lower,” “on,” “above,” “over,” “downwardly,” “upwardly” and the like may be used throughout the disclosure while making reference to the features as illustrated in the drawings. The features may be oriented differently (e.g., rotated 90 degrees or at other orientations) and the spatially relative terms used herein may be interpreted accordingly.

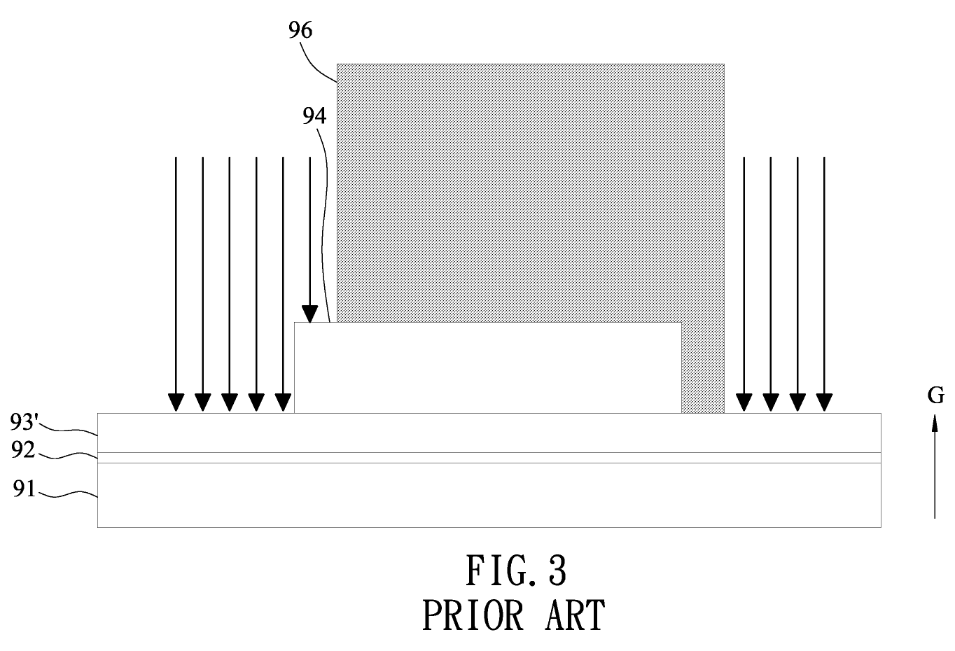

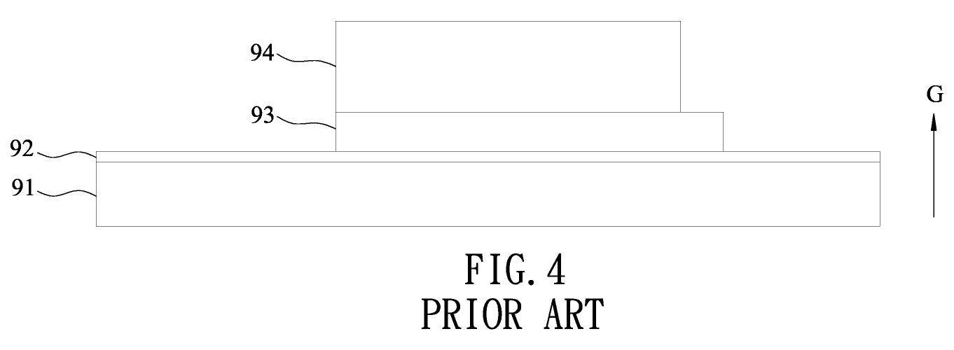

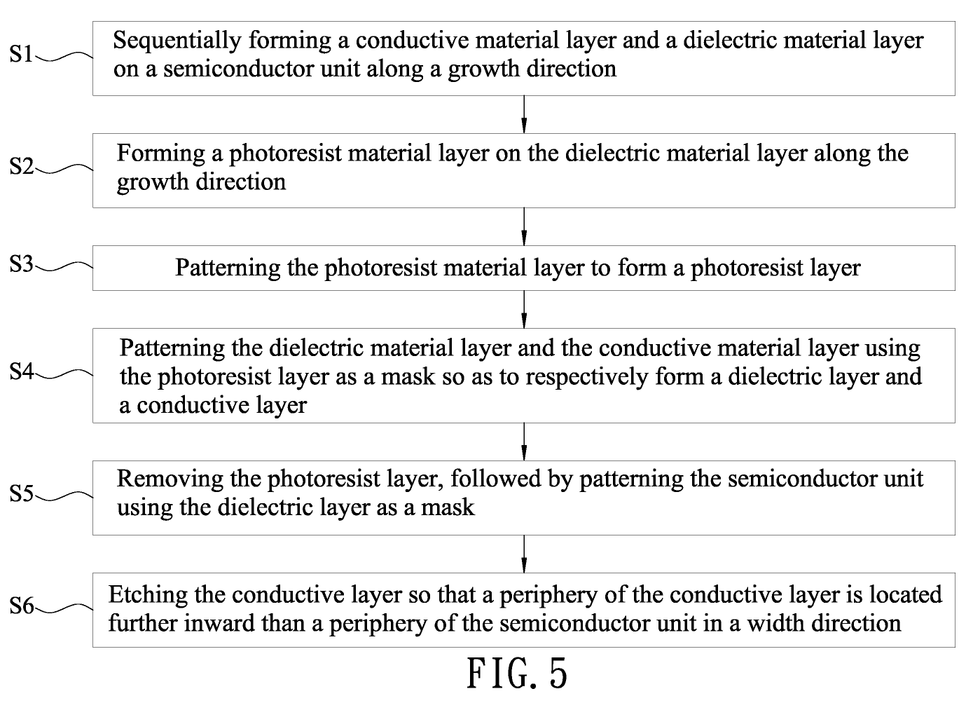

Referring to FIG. 5, an embodiment of a method for manufacturing a semiconductor device includes steps a) to e).

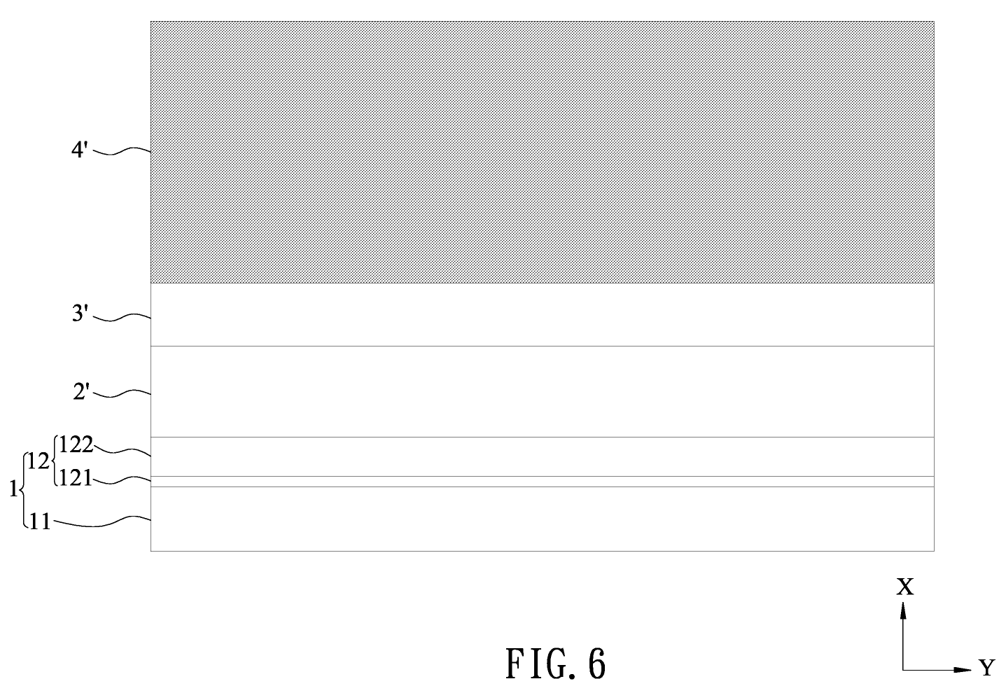

Referring to FIG. 6, in step a) (also referred to as step S1) a conductive material layer 2’ and a dielectric material layer 3’ are sequentially formed on a semiconductor unit 1 along a growth direction (X).

In some embodiments, the semiconductor unit 1 sequentially includes a semiconductor layer 11 and a III-V compound layer 12 in the growth direction (X). In some embodiments, the semiconductor layer 11 and the III-V compound layer 12 are made of different materials. In some embodiments, the III-V compound layer 12 includes a barrier layer 121 and a doping layer 122 in the growth direction (X). The barrier layer 121 may include aluminum gallium nitride. The doping layer 122 may include a p-type doped III-V compound. In certain embodiments, the doping layer 122 is made of magnesium-doped gallium nitride.

In some embodiments, the conductive material layer 2’ is formed on the doping layer 122 of the III-V compound layer 12. The conductive material layer 2’ may include a metal material or a ceramic material. In certain embodiments, the conductive material layer 2’ includes titanium nitride. In some embodiments, the dielectric material layer 3’ includes silicon nitride or silicon oxide.

In step b) (also referred to as step S2), a photoresist material layer 4’ is formed on the dielectric material layer 3’ along the growth direction (X).

Referring to FIG. 7, in step c) (also referred to as step S3), the photoresist material layer 4’ is patterned to form a photoresist layer 4.

In some embodiments, after patterning the photoresist material layer 4’, the photoresist layer 4 is formed with a particular pattern. An example of the particular pattern may be a gate pattern, but is not limited thereto.

In step d) (also referred to as step S4), the dielectric material layer 3’ and the conductive material layer 2’ are patterned using the photoresist layer 4 as a mask so as to respectively form a dielectric layer 3 and a conductive layer 2.

In some embodiments, step d) is performed by an anisotropic etching procedure to transfer the particular pattern from the photoresist layer 4 to the dielectric layer 3 and the conductive layer 2. In some embodiments, the anisotropic etching procedure includes a reactive ion etching procedure, an inductively coupled plasma procedure, etc.

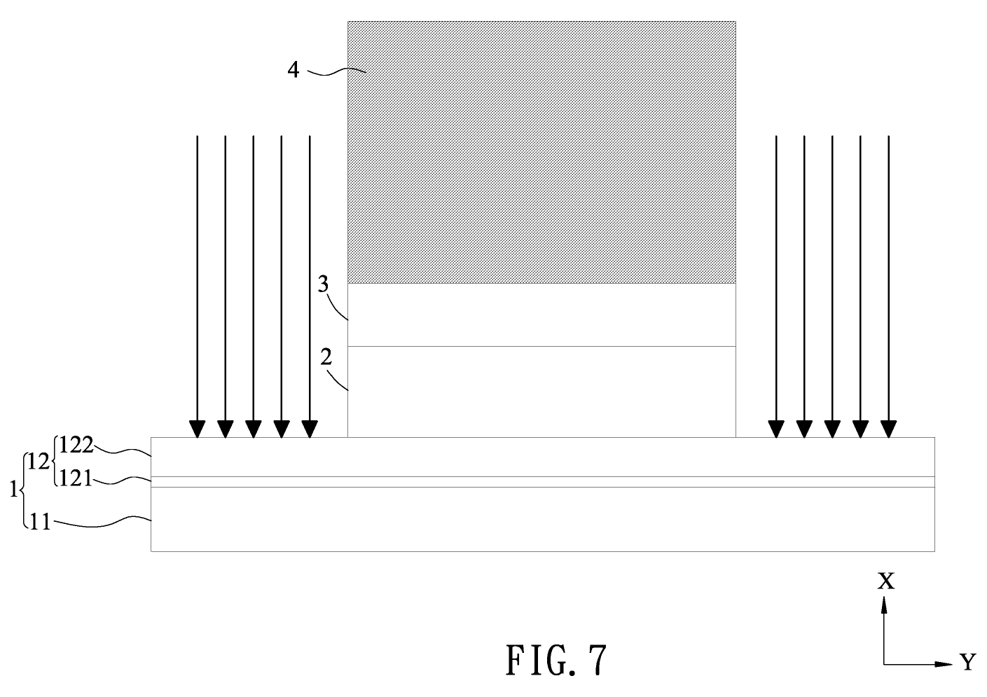

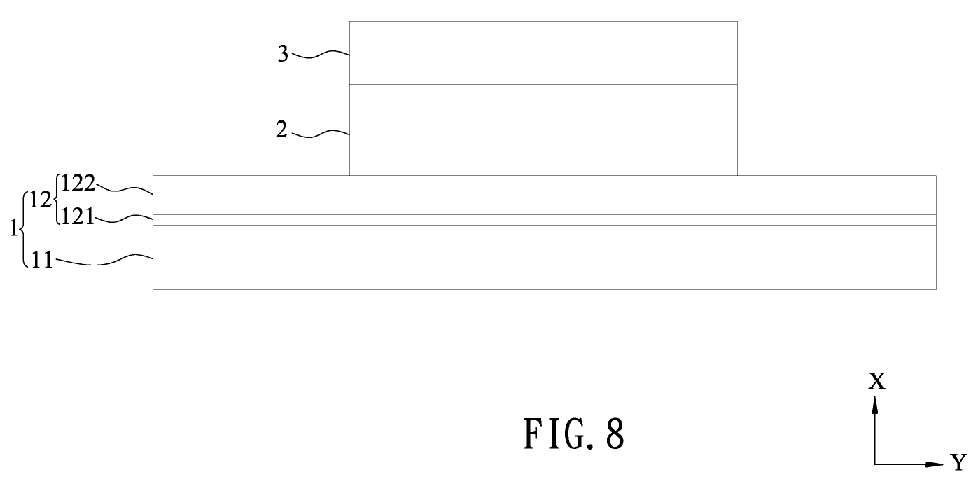

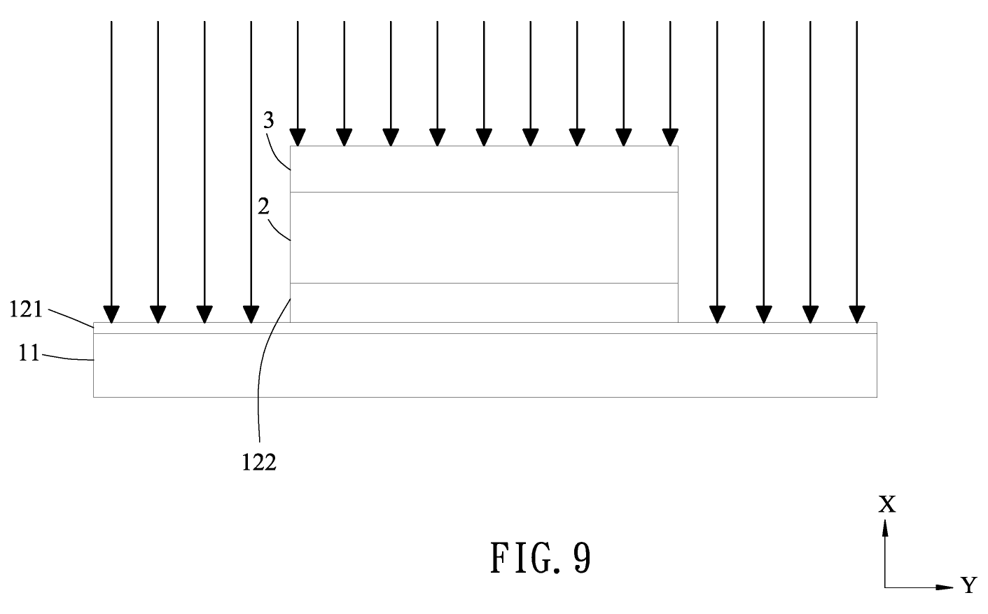

Referring to FIGS. 8 and 9, in step e) (also referred to as step S5), the photoresist layer 4 is removed, followed by patterning the doping layer 122 of the semiconductor unit 1 using the dielectric layer 3 as a mask.

In some embodiments, patterning the doping layer 122 of the conductive unit 1 in step e) is performed by an anisotropic etching procedure to transfer the particular pattern from the dielectric layer 3 to the doping layer 122.

The particular pattern of the conductive layer 2 and the particular pattern of the doping layer 122 of the semiconductor unit 1 are respectively determined by the photoresist layer 4 and the dielectric layer 3. In addition, the particular pattern of the dielectric layer 3 is determined by the photoresist layer 4. Thus, misalignment between the conductive layer 2 and the doping layer 122 of the semiconductor unit 1 may be avoided. In other words, a periphery of the conductive layer 2 and a periphery of the doping layer 122 of the semiconductor unit 1 in a width direction (Y) which is perpendicular to the growth direction (X) are aligned with each other.

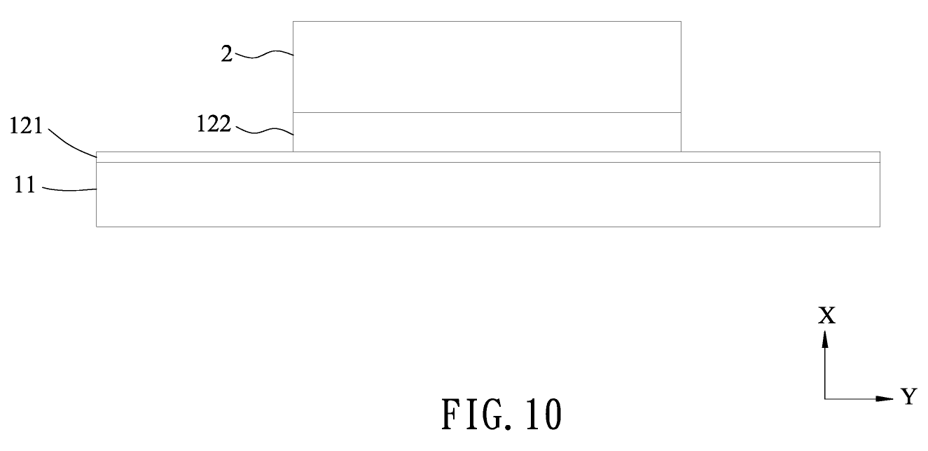

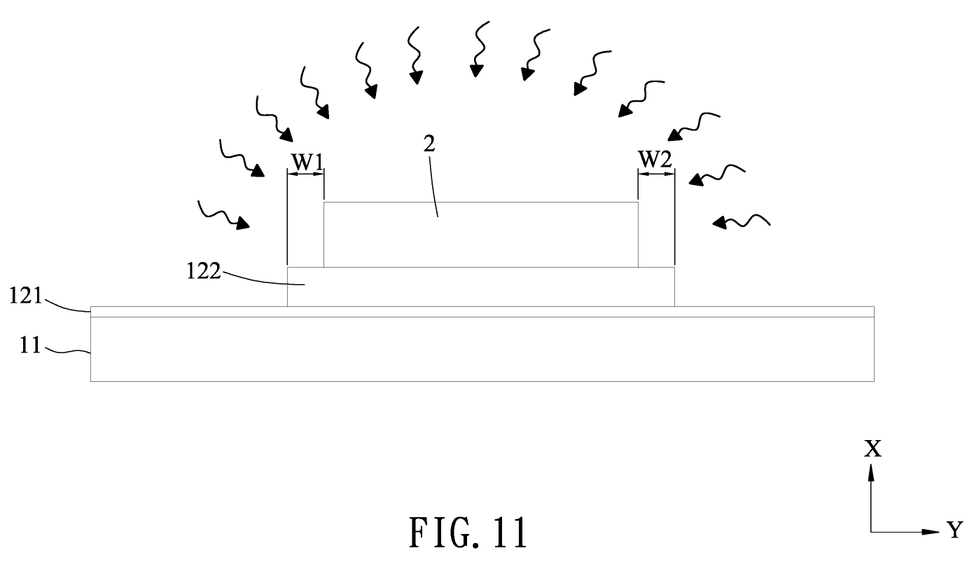

Referring to FIGS. 10 and 11, the method further includes step f) (also referred to as step S6) which involves etching the conductive layer 2 so that the periphery of the conductive layer 2 is located further inward than a periphery of the semiconductor unit 1 in the width direction (Y). In some embodiments, the method further includes, before step f), step g) removing the dielectric layer 3.

In some embodiments, step f) is performed by an isotropic etching procedure (e.g., a wet etching procedure) to etch the conductive layer 2 so that a thickness thereof in the growth direction (X) and a width thereof in the width direction (Y) are reduced. After etching, the periphery of the conductive layer 2 is located further inward than the periphery of the doping layer 122 in the width direction (Y), and the periphery of the conductive layer 2 and the periphery of the doping layer 122 are separated by a distance in the width direction (Y). In some embodiments, in the width direction (Y), one of two edges of the conductive layer 2 and a respective one of two edges of the semiconductor unit 1 that is adjacent to the one of the two edges of the conductive layer 2 are separated by a distance D1, and another one of the two edges of the conductive layer 2 and a respective one of the two edges of the semiconductor unit 1 that is adjacent to the another one of the two edges of the conductive layer 2 are separated by a distance D2. In some embodiments, when process variations are negligible, the distance D1 and the distance D2 are the same. In certain embodiments, one of two edges of the conductive layer 2 and a respective one of two edges of the doping layer 122 that is adjacent to the one of the two edges of the conductive layer 2 are separated by a first distance W1, and another one of the two edges of the conductive layer 2 and a respective one of the two edges of the doping layer 122 that is adjacent to the another one of the two edges of the conductive layer 2 are separated by a second distance W2. In some embodiments, when process variations are negligible, the first distance W1 and the second distance W2 are the same, and thus a symmetric structure may be obtained.

In some embodiments, in the width direction (Y), the width of the conductive layer 2 is less than a width of the doping layer 122, and thus a staircase-like structure is formed. The symmetric structure or the staircase-like structure of this disclosure may be formed as a gate structure. The gate structure having the symmetric shape may ensure a transistor exhibits stable electrical characteristics. Compared to the conventional structure shown in FIG. 4 in which a periphery of the conductive layer 94 and a periphery of the p-doped layer 93 are not flush with each other along the growth direction (G), the structure of the disclosure shown in FIG. 10, in which the periphery of the conductive layer 2 and the periphery of the doping layer 122 in the width direction (Y) are flush with each other along the growth direction (X), so that the method of the present disclosure is less likely to form footing defects while performing the wet etching procedure. Thus, it is much easier to precisely form the gate structure having the symmetric shape so that the transistor obtained from the method may exhibit stable static electrical characteristics, dynamic electrical characteristics, and better reliability. Hence, compared to the conventional method, the method of the present disclosure is able to form the gate structure having the symmetric shape by a relatively simple procedure, and may not be limited by alignment accuracy of an aligner.

It should be noted that the conductive layer 2 may also be etched without removal of the dielectric layer 3 (i.e., step g) is not performed). Thus, the thickness of the conductive layer 2 may not be reduced, while the width thereof may be reduced.

In summary, with the particular process involving simultaneously patterning the dielectric layer 3 and the conductive layer 2 through the photoresist layer 4, followed by patterning the semiconductor unit 1 using the dielectric layer 3 as the mask, the method for manufacturing the semiconductor device requires only a single photoresist-involved photolithography process, thereby simplifying the manufacturing procedures. In addition, because there is no need to perform photoresist-involved photolithography processes twice, alignment deviations of an aligner may be avoided, so that misalignment between the conductive layer 2 and the semiconductor unit 1 may be prevented, thereby significantly enhancing manufacturing yield. Thus, an object of the present disclosure can indeed be achieved.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, said one or more features may be singled out and practiced alone without said another one or more features or specific details. It should be further noted that one or more features or specific details from one embodiment may be practiced together with one or more features or specific details from another embodiment, where appropriate, in the practice of the disclosure.

While the disclosure has been described in connection with what is(are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

What is claimed is:

1. A method for manufacturing a semiconductor device, comprising the steps of:
a) sequentially forming a conductive material layer and a dielectric material layer on a semiconductor unit along a growth direction;
b) forming a photoresist material layer on the dielectric material layer along the growth direction;
c) patterning the photoresist material layer to form a photoresist layer;
d) patterning the dielectric material layer and the conductive material layer using the photoresist layer as a mask so as to respectively form a dielectric layer and a conductive layer; and
e) removing the photoresist layer, followed by patterning the semiconductor unit using the dielectric layer as a mask.

2. The method as claimed in claim 1, further comprising:
f) etching the conductive layer so that, in a width direction that is perpendicular to the growth direction, a periphery of the conductive layer is located further inward than a periphery of the semiconductor unit.

3. The method as claimed in claim 2, further comprising, before step f), g) removing the dielectric layer.

4. The method as claimed in claim 3, wherein each of the conductive layer and the semiconductor unit has two edges in the width direction, one of the two edges of the conductive layer and a respective one of the two edges of the semiconductor unit that is adjacent to the one of the two edges of the conductive layer are separated by a first distance in the width direction, and another one of the two edges of the conductive layer and a respective one of the two edges of the semiconductor unit that is adjacent to the another one of the two edges of the conductive layer are separated by a second distance in the width direction, the first distance and the second distance being the same.

5. The method as claimed in claim 2, wherein each of the conductive layer and the semiconductor unit has two edges in the width direction, one of the two edges of the conductive layer and a respective one of the two edges of the semiconductor unit that is adjacent to the one of the two edges of the conductive layer are separated by a first distance in the width direction, and another one of the two edges of the conductive layer and a respective one of the two edges of the semiconductor unit that is adjacent to the another one of the two edges of the conductive layer are separated by a second distance in the width direction, the first distance and the second distance being the same.

6. The method as claimed in claim 2, wherein step f) is performed by an isotropic etching procedure.

7. The method as claimed in claim 6, wherein the isotropic etching procedure includes a wet etching process.

8. The method as claimed in claim 1, wherein in step a), the semiconductor unit sequentially includes a semiconductor layer and a III-V compound layer in the growth direction, the conductive material layer being formed on the III-V compound layer.

9. The method as claimed in claim 8, wherein the semiconductor layer and the III-V compound layer are made of different materials.

10. The method as claimed in claim 8, wherein the III-V compound layer sequentially includes a barrier layer and a doping layer in the growth direction, the doping layer being patterned in step e).

11. The method as claimed in claim 10, wherein the doping layer includes magnesium-doped gallium nitride.

12. The method as claimed in claim 10, further comprising:
f) etching the conductive layer so that, in a width direction that is perpendicular to the growth direction, a periphery of the conductive layer is located further inward than a periphery of the doping layer.

13. The method as claimed in claim 12, wherein each of the conductive layer and the doping layer has two edges in the width direction, one of the two edges of the conductive layer and a respective one of the two edges of the doping layer that is adjacent to the one of the two edges of the conductive layer are separated by a first distance in the width direction, and another one of the two edges of the conductive layer and a respective one of the two edges of the doping layer that is adjacent to the another one of the two edges of the conductive layer are separated by a second distance in the width direction, the first distance and the second distance being the same.

14. The method as claimed in claim 10, wherein a width of the conductive layer is less than a width of the doping layer in a width direction that is different from the growth direction.

15. The method as claimed in claim 1, wherein in step a), the conductive material layer includes a metal material or a ceramic material.

16. The method as claimed in claim 15, wherein the conductive material layer includes titanium nitride.

17. The method as claimed in claim 1, wherein in step a), the dielectric material layer includes one of silicon nitride and silicon oxide.

18. The method as claimed in claim 1, wherein step d) is performed by an anisotropic etching procedure.

19. The method as claim in claim 17, wherein the anisotropic etching procedure includes a reactive ion etching process, an inductively coupled plasma process, or a combination thereof.

20. The method as claimed in claim 1, wherein patterning the semiconductor unit in step e) is performed by an anisotropic etching procedure.
